(19) United States
(12) Patent Application Publication
(10) Pub. No.: US 2015/0287893 A1
(43) Pub. Date: Oct. 8, 2015

(54) PACKAGE MATERIAL FOR PACKAGING PHOTOELECTRIC DEVICE AND PACKAGE

(71) Applicant: Genesis Photonics Inc., Tainan City (TW)

(72) Inventors: Kuan-Chieh Huang, Tainan City (TW); Chun-Ming Tseng, Tainan City (TW); Wen-Jie Lu, Kaohsiung City (TW); Tsung-Tse Wu, Kaohsiung City (TW); Wei-Ling Su, Tainan City (TW); Kuan-Yung Liao, Taipei City (TW); Gwo-Jiun Sheu, Tainan City (TW)

(21) Appl. No.: 14/676,821

(22) Filed: Apr. 2, 2015

(30) Foreign Application Priority Data
Apr. 2, 2014 (TW) 103112351

(51) Int. Cl. H01L 33/58; H01L 33/50; H01L 33/54; H01L 33/56

(52) U.S. Cl. CPC H01L 33/58; H01L 33/56; H01L 33/502; H01L 33/54; H01L 2933/0091

(57) ABSTRACT

A package material for packaging a photoelectric device includes a first molding portion and a second molding portion. The first molding portion is disposed on the photoelectric device. The first molding portion includes a first molding compound and a plurality of nano-scale metal oxide particles, wherein the nano-scale metal oxide particles are doped in the first molding compound. The second molding portion is disposed on the first molding portion and away from the photoelectric device. The second molding portion includes a second molding compound and a plurality of submicron-scale metal oxide particles, wherein the submicron-scale metal oxide particles are doped in the second molding compound. A whole refractive index of the first molding portion is larger than a whole refractive index of the second molding portion.

### BACKGROUND OF THE INVENTION

1. Field of the Invention

The invention relates to a package material and a package and, more particularly, to a package material for packaging a photoelectric device and a package.

2. Description of the Prior Art

Referring to FIG. 1, FIG. 1 is a schematic view illustrating a light emitting diode (LED) package 1 of the prior art. The LED package 1 includes a package substrate 10, a light emitting diode chip 12 and a molding compound 14. The light emitting diode chip 12 is disposed on the package substrate 10 and the molding compound 14 is dispensed on the package substrate 10 and the light emitting diode chip 12, so as to package the light emitting diode chip 12. In general, if there are only phosphor particles doped in the molding compound 14, light cannot be refracted and scattered well, such that the LED package 1 cannot generate uniform light. Especially, the light at large viewing angle will be more non-uniform, such that the visual effect will be influenced.

### SUMMARY OF THE INVENTION

The disclosure provides a package material for packaging a photoelectric device and a package, so as to solve the aforementioned problems.

The package material for packaging a photoelectric device of the disclosure comprises a first molding portion and a second molding portion. The first molding portion is disposed on the photoelectric device. The first molding portion comprises a first molding compound and a plurality of nano-scale metal oxide particles, wherein the nano-scale metal oxide particles are doped in the first molding compound. The second molding portion is disposed on the first molding portion and away from the photoelectric device. The second molding portion comprises a second molding compound and a plurality of submicron-scale metal oxide particles, wherein the submicron-scale metal oxide particles are doped in the second molding compound. A whole refractive index of the first molding portion is larger than a whole refractive index of the second molding portion.

According to an embodiment of the disclosure, the package material further comprises a plurality of phosphor particles doped in the second molding compound, and a concentration of the phosphor particles in the second molding compound is between 3 wt % and 40 wt %.

According to an embodiment of the disclosure, the package material further comprises a phosphor portion disposed on the second molding compound, and the phosphor portion comprises a plurality of phosphor particles.

The package of the disclosure comprises the aforementioned photoelectric device and the aforementioned package material. The photoelectric device comprises a support and a light emitting diode, wherein the light emitting diode is disposed on the support. The package material is disposed on the support and covers the light emitting diode.

As the above mentioned, the disclosure disposes the first molding portion, which is doped with the nano-scale metal oxide particles, and the second molding portion, which is doped with the submicron-scale metal oxide particles, on the photoelectric device, such that the whole refractive index of the first molding portion is larger than the whole refractive index of the second molding portion, wherein the first molding portion is close to the photoelectric device and the second molding portion is away from the photoelectric device. Accordingly, light emitted by the light emitting diode will pass through the first molding portion with larger refractive index first, so as to enhance the quantity of light output. Afterward, the light will pass through the second molding portion and be scattered by the submicron-scale metal oxide particles, so as to generate uniform light. Furthermore, when the phosphor particles are doped in the second molding portion or the phosphor portion is disposed on the second molding portion, the difference between the highest correlated color temperature and the lowest correlated color temperature of the package of the disclosure will decrease. Accordingly, the light emitted by the package will be more uniform and the quantity of phosphor particles used in the package can be reduced.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic view illustrating an LED package of the prior art.

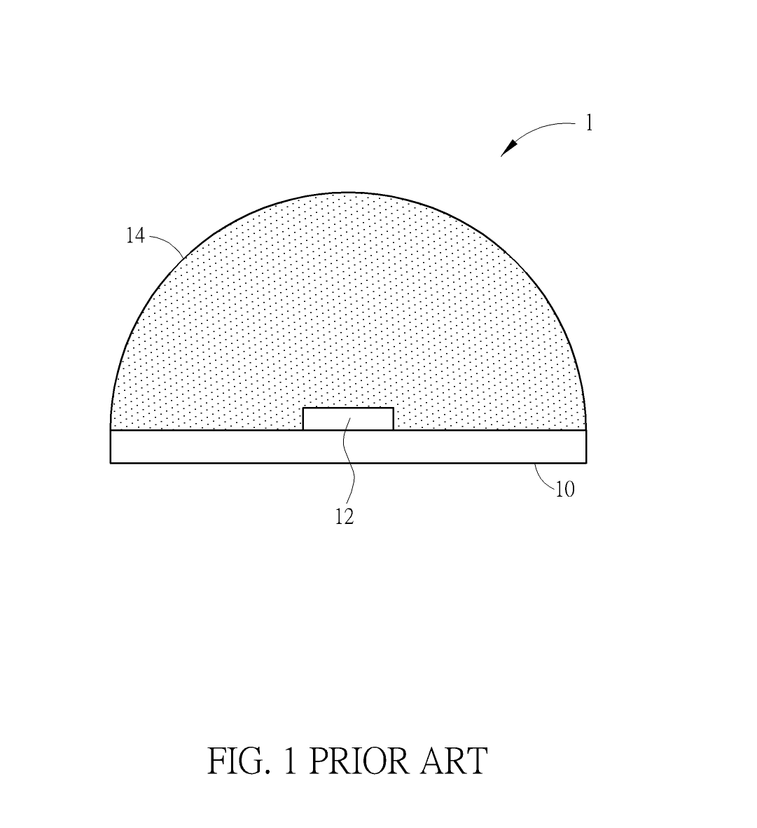

FIG. 2 is a schematic view illustrating a package according to a first embodiment of the disclosure.

FIG. 3 is a schematic view illustrating a package according to a second embodiment of the disclosure.

FIG. 4 is a schematic view illustrating a package according to a third embodiment of the disclosure.

FIG. 5 is a schematic view illustrating a variation of correlated color temperature associated with light emitting angle.

FIG. 6 is a schematic view illustrating another variation of correlated color temperature associated with light emitting angle.

FIG. 7 is a schematic view illustrating a package according to a fourth embodiment of the disclosure.

FIG. 8 is a schematic view illustrating a package according to a fifth embodiment of the disclosure.

### DETAILED DESCRIPTION

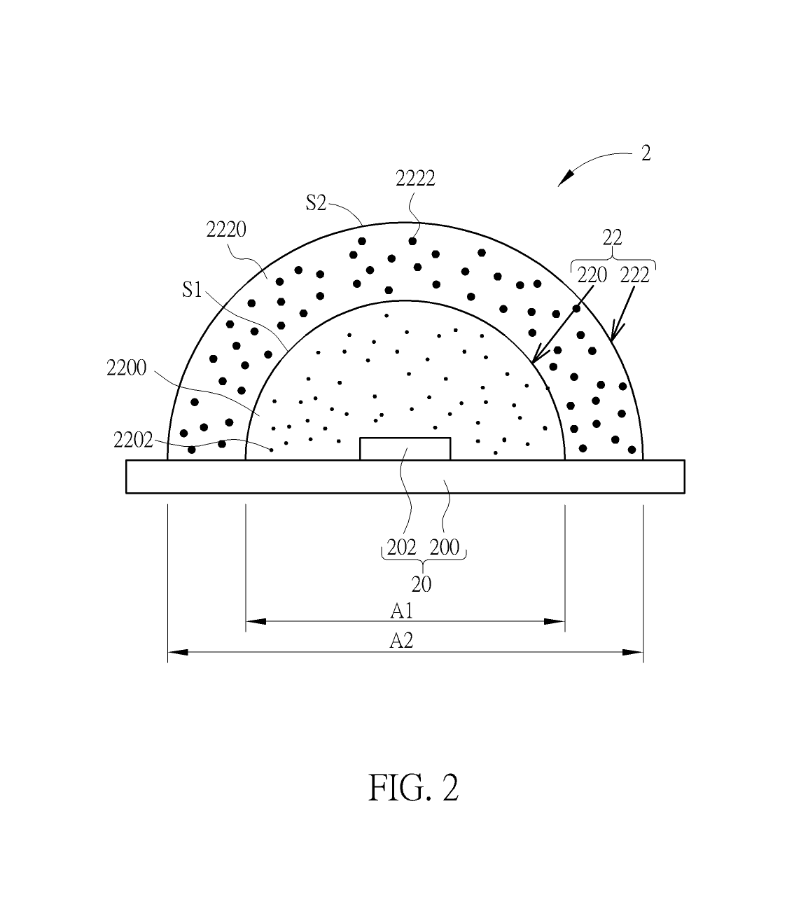

Referring to FIG. 2, FIG. 2 is a schematic view illustrating a package 2 according to a first embodiment of the disclosure. As shown in FIG. 2, the package 2 comprises a photoelectric device 20 and a package material 22, wherein the package material 22 is used for packaging the photoelectric device 20. The photoelectric device 20 comprises a support 200 and a light emitting diode (LED) 202, wherein the LED 202 is disposed on the support 200. The package material 22 is disposed on the support 200 and covers the LED 202. The package material 22 comprises a first molding portion 220 and a second molding portion 222.

The first molding portion 220 is disposed on the support 200 of the photoelectric device 20 and covers the LED 202. The first molding portion 220 comprises a first molding compound 2200 and a plurality of nano-scale metal oxide particles 2202, wherein the nano-scale metal oxide particles 2202 are doped in the first molding compound 2200. In an embodiment, the nano-scale metal oxide particles 2202 are doped in the first molding compound 2200 uniformly. The second molding portion 222 is disposed on the first molding portion 220 and away from the photoelectric device 20. In this embodiment, the second molding portion 222 covers the first molding portion 220, such that a projection area A2 of the second molding portion 222 projected on the support 200 is larger than a projection area A1 of the first molding portion 220 projected on the support 200. However, the projection area of the second molding portion 222 projected on the support 200 maybe equal to the projection area of the first molding portion 220 projected on the support 200 according to practical applications. Furthermore, a shape of an outer surface S2 of the second molding portion 222 is identical to a shape of an outer surface S1 of the first molding portion 220, such that the shape of the second molding portion 222 and the shape of light refracted by the first molding portion 220 may match pretty well, so as to the uniformity of light emitted by the package 2. As shown in FIG. 2, the outer surface S2 of the second molding portion 222 and the outer surface S1 of the first molding portion 220 both are, but not limited to, arc-shaped. The second molding portion 222 comprises a second molding compound 2220 and a plurality of submicron-scale metal oxide particles 2222, wherein the submicron-scale metal oxide particles 2222 are doped in the second molding compound 2220. In an embodiment, the submicron-scale metal oxide particles 2222 are doped in the second molding compound 2220 uniformly.

In this embodiment, a primary diameter of the nano-scale metal oxide particles 2202 is between 1 nm and 100 nm, and a primary diameter of the submicron-scale metal oxide particles 2222 is between 0.1 μm and 1 μm. Preferably, the primary diameter of the nano-scale metal oxide particles 2202 may be between 20 nm and 40 nm, and the primary diameter of the submicron-scale metal oxide particles 2222 may be between 0.3 μm and 0.6 μm. Furthermore, a concentration of the nano-scale metal oxide particles 2202 in the first molding compound 2200 is between 0.001 wt % and 0.5 wt %, and a concentration of the submicron-scale metal oxide particles 2222 in the second molding compound 2220 is between 0.001 wt % and 0.5 wt %. In other words, the concentration of the nano-scale metal oxide particles 2202 in the first molding compound 2200 may be smaller than or equal to the concentration of the submicron-scale metal oxide particles 2222 in the second molding compound 2220, so as to enhance light emitting efficiency. It should be noted that if the concentration of the nano-scale metal oxide particles 2202 is too small, the refractive index of the first molding compound 2200 cannot be enhanced well; if the concentration of the nano-scale metal oxide particles 2202 is too large, the nano-scale metal oxide particles 2202 may cohere easily to cause light shielding effect; if the concentration of the submicron-scale metal oxide particles 2222 is too small, the light cannot be scattered well; and if the concentration of the submicron-scale metal oxide particles 2222 is too large, the light emitting effect will be influenced. In practical applications, the first molding compound 2200 and the second molding compound 2220 may be silicone, epoxy or other molding compounds, and the first molding compound 2200 maybe identical to or different from the second molding compound 2220. Moreover, the nano-scale metal oxide particles 2202 and the submicron-scale metal oxide particles 2222 maybe TiO₂, ZrO₂, ZnO, Al₂O₃ or other metal oxide particles.

In this embodiment, a whole refractive index of the first molding portion 220 is larger than a whole refractive index of the second molding portion 222. Specifically, since the diameter of the nano-scale metal oxide particles 2202 is smaller, the light emitted by the LED 202 may pass through the nano-scale metal oxide particles 2202 easily, so as to enhance the whole refractive index of the first molding portion 220 and reduce the probability of total reflection, such that the quantity of light output can be enhanced. Furthermore, since the diameter of the submicron-scale metal oxide particles 2222 is larger, the light come from the first molding portion 220 will be scattered by the submicron-scale metal oxide particles 2222 easily, so as to generate uniform light. In other words, the light emitted by the LED 202 will pass through the first molding portion 220 with larger refractive index first, so as to enhance the quantity of light output, and then the light will pass through the second molding portion 222 and be scattered by the submicron-scale metal oxide particles 2222, so as to generate uniform light. It should be noted that the submicron-scale metal oxide particles 2222 may be mesoporous structure and a pore size of the mesoporous structure is between 2 nm and 5 nm. When the submicron-scale metal oxide particles 2222 is mesoporous structure, the contact area between the light and the submicron-scale metal oxide particles 2222 will increase, such that the light scattering effect will be enhanced. Still further, a contact interface exists between the first molding portion 220 and the second molding portion 222 (i.e. the outer surface S1 of the first molding portion 220), and a roughness (Rms) of the contact interface is larger than or equal to 1 nm, so as to enhance the quantity of light output and provide good contact effect.

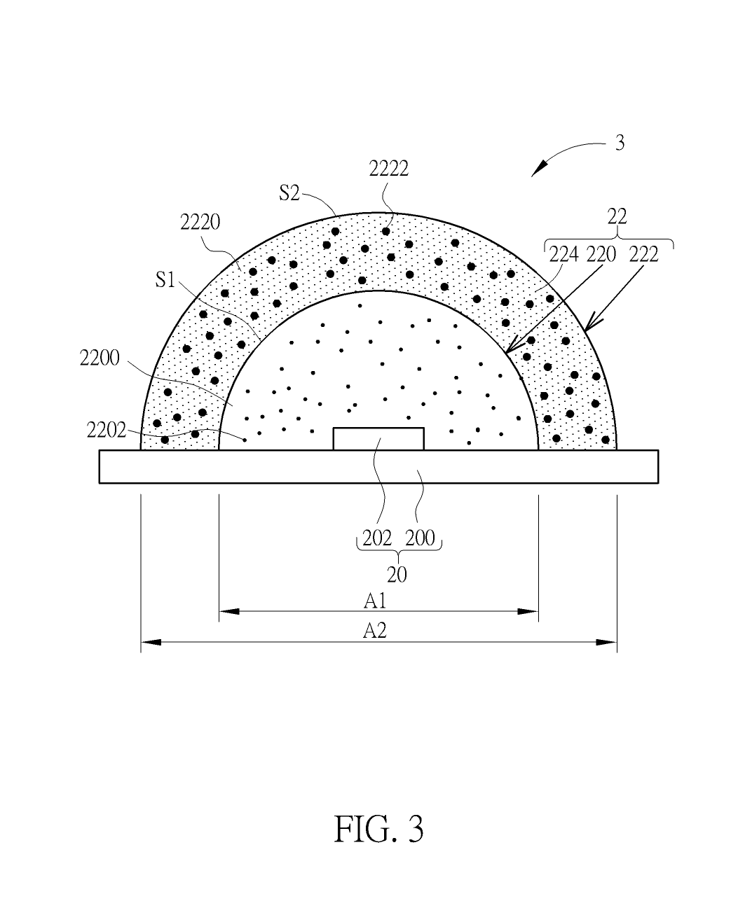

Referring to FIG. 3 along with FIG. 2, FIG. 3 is a schematic view illustrating a package 3 according to a second embodiment of the disclosure. The main difference between the package 3 and the aforementioned package 2 is that the package material 22 of the package 3 further comprises a plurality of phosphor particles 224 doped in the second molding compound 2220, wherein a concentration of the phosphor particles 224 in the second molding compound 2220 is between 3 wt % and 40 wt %. It should be noted that the concentration of the phosphor particles 224 maybe lower if the package 3 has a reflective layer or the like, and the concentration of the phosphor particles 224 may be higher if the package 3 does not has a reflective layer or the like. In this embodiment, the light scattered by the submicron-scale metal oxide particles 2222 may excite more phosphor particles 224, so as to reduce the quantity of phosphor particles 224 used in the package 3. Furthermore, since the submicron-scale metal oxide particles 2222 can make the light uniform, the mixed light generated by exciting the phosphor particles 224 will be more uniform. It should be noted that the same elements in FIG. 3 and FIG. 2 are represented by the same numerals, so the repeated explanation will not be depicted herein again.

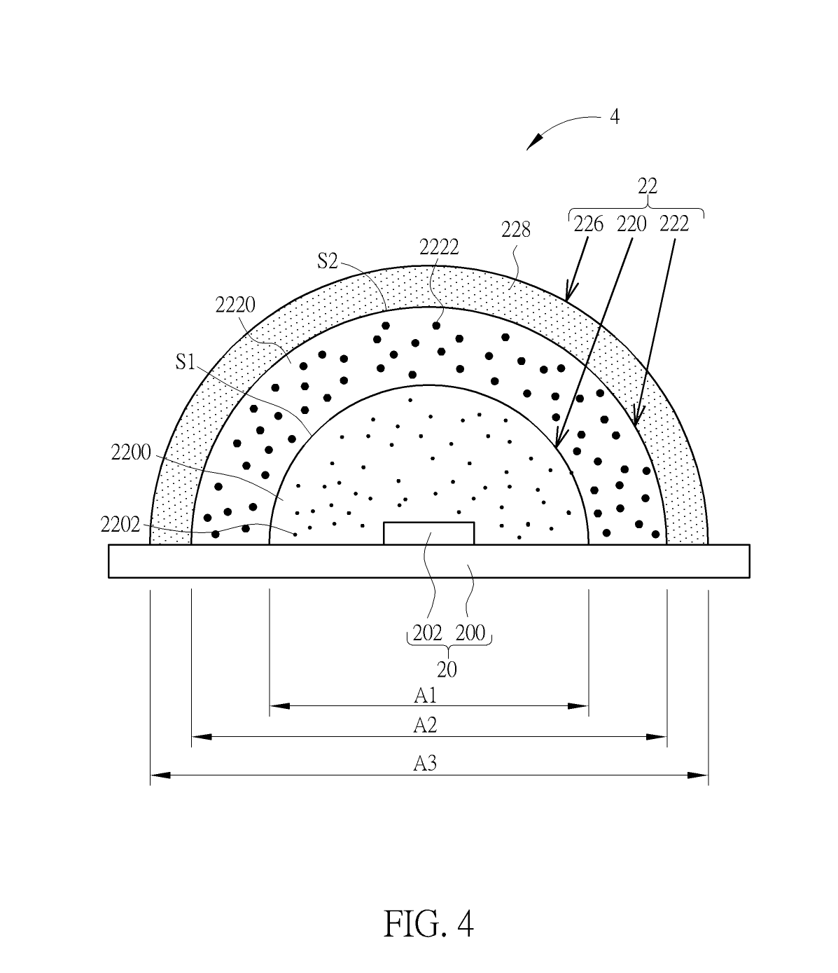

Referring to FIG. 4 along with FIG. 2, FIG. 4 is a schematic view illustrating a package 4 according to a third embodiment of the disclosure. The main difference between the package 4 and the aforementioned package 2 is that the package material 22 of the package 4 further comprises a phosphor portion 226 disposed on the second molding compound 222, wherein the phosphor portion 226 comprises a plurality of phosphor particles 228. In this embodiment, the phosphor portion 226 covers the second molding portion 222, such that a projection area A3 of the phosphor portion 226 projected on the support 200 is larger than the projection area A2 of the second molding portion 222 projected on the support 200. Accordingly, the light scattered by the submicron-scale metal oxide particles 2222 can be used to excite the phosphor particles 228 effectively. However, the projection area A3 of the phosphor portion 226 projected on the support 200 may be equal to the projection area A2 of the second molding portion 222 projected on the support 200 according to practical applications. In practical applications, the phosphor particles 228 may be doped in a transparent glue to form the phosphor portion 226. As the above mentioned, since the light scattered by the submicron-scale metal oxide particles 2222 can excite more phosphor particles 228, the quantity of phosphor particles 228 used in the package 4 can be reduced effectively. It should be noted that the same elements in FIG. 4 and FIG. 2 are represented by the same numerals, so the repeated explanation will not be depicted herein again.

In other words, the disclosure may dope the phosphor particles 224 in the second molding compound 2220 immediately or dispose the phosphor portion 226 with the phosphor particles 228 on the second molding compound 2220 according to practical applications. Since the submicron-scale metal oxide particles 2222 in the second molding portion 222 can scatter light, the difference between the highest correlated color temperature and the lowest correlated color temperature of the package 3 or 4 of the disclosure will decrease when the phosphor particles 224 are doped in the second molding portion 222 (as shown in FIG. 3) or the phosphor portion 226 is disposed on the second molding portion 222 (as shown in FIG. 4). Accordingly, the light emitted by the package 3 or 4 will be more uniform and the probability of generating light spot will be reduced.

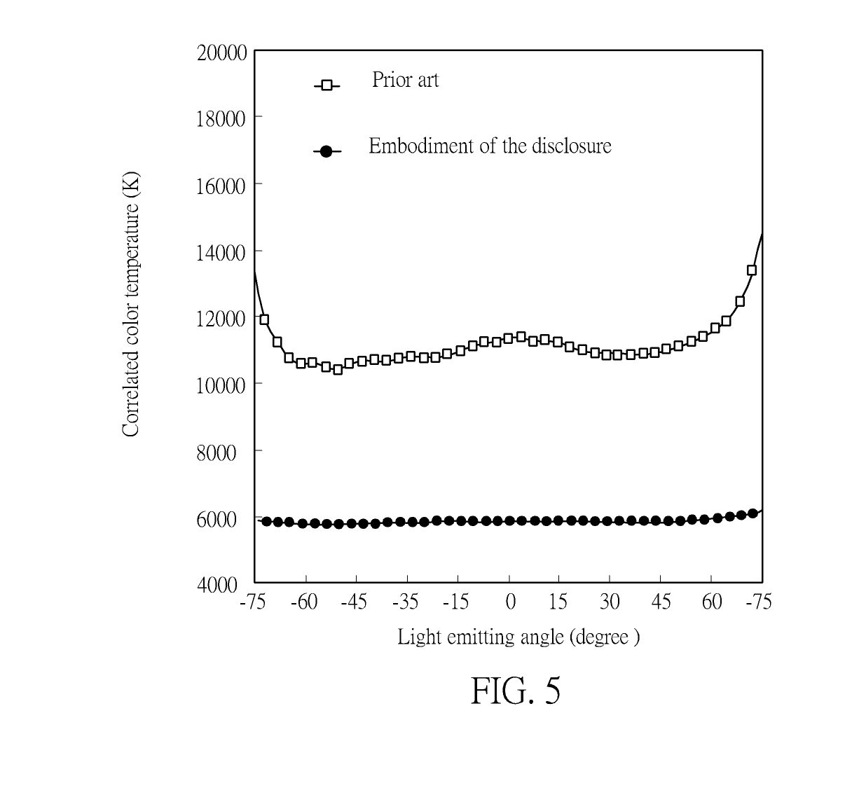

Referring to FIG. 5, FIG. 5 is a schematic view illustrating a variation of correlated color temperature associated with light emitting angle. The variation shown in FIG. 5 is measured by a package with a reflective layer or the like according to an embodiment of the disclosure and the prior art. As shown in FIG. 5, compared to the prior art, the difference between the highest correlated color temperature and the lowest correlated color temperature of the package with a reflective layer or the like of the disclosure within a light emitting range between positive and negative 75 degrees, which is measured from a light emitting angle to a normal of the light emitting diode, decreases. Furthermore, compared to the prior art, an average correlated color temperature of the package with a reflective layer or the like of the disclosure within a light emitting range between positive and negative 75 degrees, which is measured from a light emitting angle to a normal of the light emitting diode, also decreases.

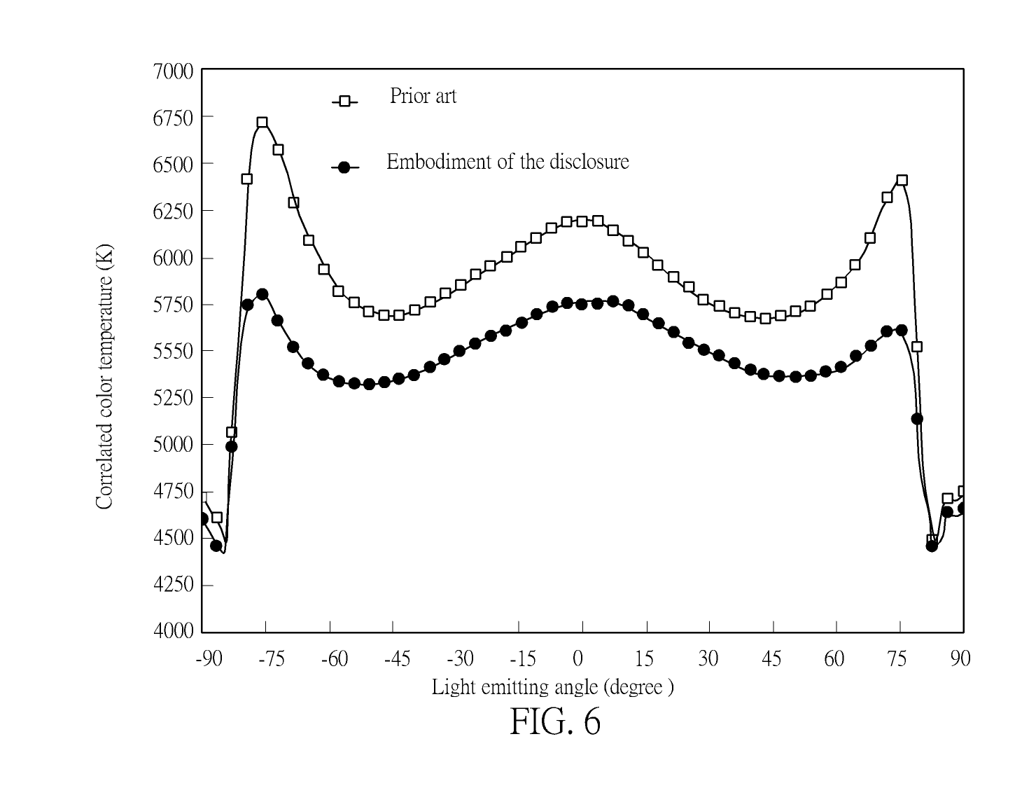

Referring to FIG. 6, FIG. 6 is a schematic view illustrating another variation of correlated color temperature associated with light emitting angle. The variation shown in FIG. 6 is measured by a package without a reflective layer or the like according to an embodiment of the disclosure and the prior art. As shown in FIG. 6, compared to the prior art, the difference between the highest correlated color temperature and the lowest correlated color temperature of the package without a reflective layer or the like of the disclosure within a light emitting range between positive and negative 90 degrees, which is measured from a light emitting angle to a normal of the light emitting diode, decreases. Furthermore, compared to the prior art, an average correlated color temperature of the package without a reflective layer or the like of the disclosure within a light emitting range between positive and negative 90 degrees, which is measured from a light emitting angle to a normal of the light emitting diode, also decreases.

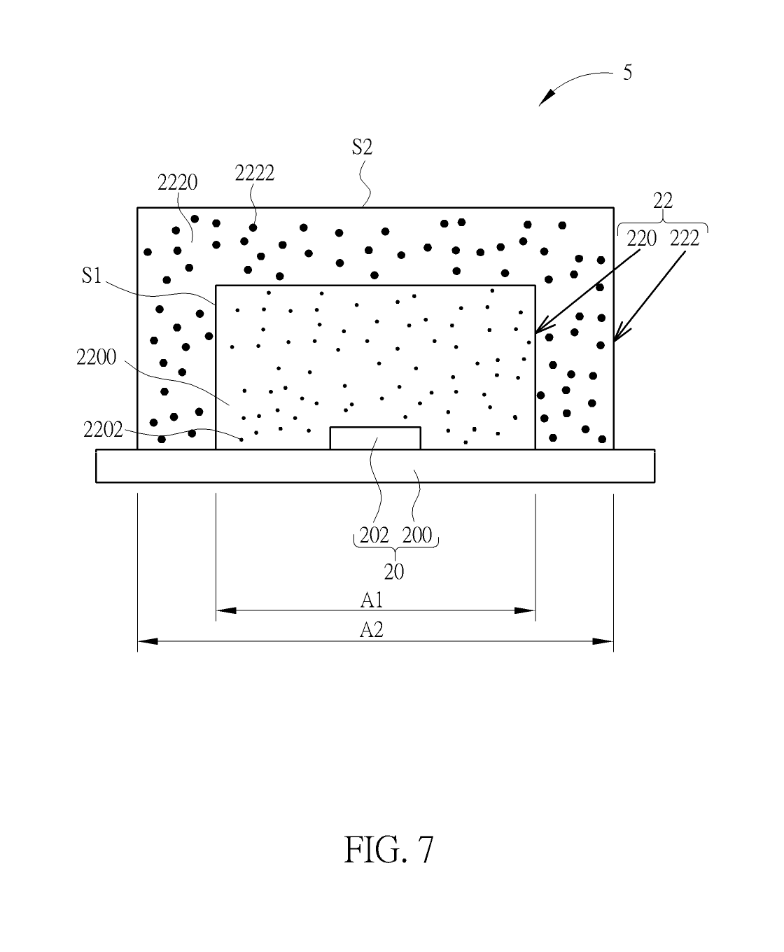

Referring to FIG. 7 along with FIG. 2, FIG. 7 is a schematic view illustrating a package 5 according to a fourth embodiment of the disclosure. The main difference between the package 5 and the aforementioned package 2 is that the outer surface S2 of the second molding portion 222 and the outer surface S1 of the first molding portion 220 of the package 5 both are rectangular. It should be noted that the shapes of the outer surface S2 of the second molding portion 222 and the outer surface S1 of the first molding portion 220 can be determined according to practical applications and are not limited to rectangular or the aforementioned arc-shaped. Furthermore, the same elements in FIG. 7 and FIG. 2 are represented by the same numerals, so the repeated explanation will not be depicted herein again.

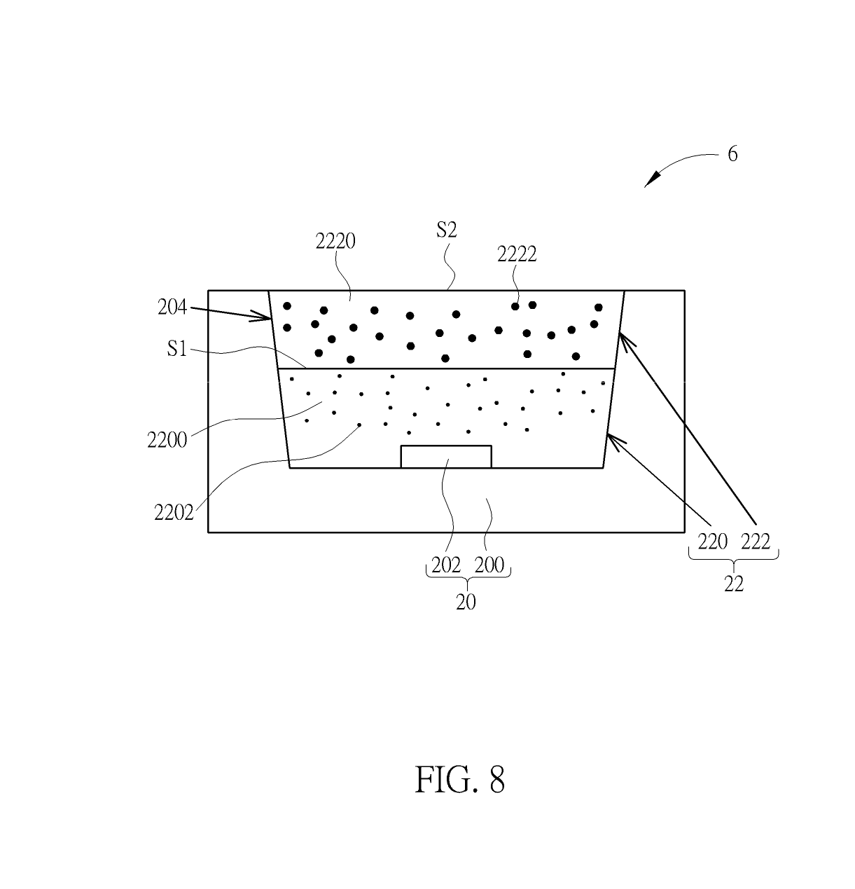

Referring to FIG. 8 along with FIG. 2, FIG. 8 is a schematic view illustrating a package 6 according to a fifth embodiment of the disclosure. The main difference between the package 6 and the aforementioned package 2 is that the support 200 of the package 6 has a recess 204, and the LED 202 and the package material 22 both are located in the recess 204. In other words, the type of the support 200 can be determined according to practical applications. It should be noted that the same elements in FIG. 8 and FIG. 2 are represented by the same numerals, so the repeated explanation will not be depicted herein again.

As mentioned in the above, the disclosure disposes the first molding portion, which is doped with the nano-scale metal oxide particles, and the second molding portion, which is doped with the submicron-scale metal oxide particles, on the photoelectric device, such that the whole refractive index of the first molding portion is larger than the whole refractive index of the second molding portion, wherein the first molding portion is close to the photoelectric device and the second molding portion is away from the photoelectric device. Accordingly, light emitted by the light emitting diode will pass through the first molding portion with larger refractive index first, so as to enhance the quantity of light output. Afterward, the light will pass through the second molding portion and be scattered by the submicron-scale metal oxide particles, so as to generate uniform light. Furthermore, through practical experiments, when the phosphor particles are doped in the second molding portion or the phosphor portion is disposed on the second molding portion, the difference between the highest correlated color temperature and the lowest correlated color temperature of the package of the disclosure will decrease. Accordingly, the light emitted by the package will be more uniform and the quantity of phosphor particles used in the package can be reduced.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A package material for packaging a photoelectric device comprising:
a first molding portion disposed on the photoelectric device, the first molding portion comprising a first molding compound and a plurality of nano-scale metal oxide particles, the nano-scale metal oxide particles being doped in the first molding compound; and
a second molding portion disposed on the first molding portion and away from the photoelectric device, the second molding portion comprising a second molding compound and a plurality of submicron-scale metal oxide particles, the submicron-scale metal oxide particles being doped in the second molding compound, a whole refractive index of the first molding portion being larger than a whole refractive index of the second molding portion.

2. The package material of claim 1, wherein a contact interface exists between the first molding portion and the second molding portion, and a roughness of the contact interface is larger than or equal to 1 nm.

3. The package material of claim 1, wherein a concentration of the nano-scale metal oxide particles in the first molding compound is between 0.001 wt % and 0.5 wt %.

4. The package material of claim 1, wherein a concentration of the submicron-scale metal oxide particles in the second molding compound is between 0.001 wt % and 0.5 wt %.

5. The package material of claim 1, wherein a primary diameter of the nano-scale metal oxide particles is between 1 nm and 100 nm, and a primary diameter of the submicron-scale metal oxide particles is between 0.1 μm and 1 μm.

6. The package material of claim 1, wherein the nano-scale metal oxide particles and the submicron-scale metal oxide particles are selected from a group consisting of TiO₂, ZrO₂, ZnO and Al₂O₃.

7. The package material of claim 1, wherein the submicron-scale metal oxide particles are mesoporous structure and a pore size of the mesoporous structure is between 2 nm and 50 nm.

8. The package material of claim 1, further comprising a plurality of phosphor particles doped in the second molding compound, a concentration of the phosphor particles in the second molding compound being between 3 wt % and 40 wt %.

9. The package material of claim 1, further comprising a phosphor portion disposed on the second molding compound, the phosphor portion comprising a plurality of phosphor particles.

10. A package comprising:
the photoelectric device of claim 1 comprising a support and a light emitting diode, the light emitting diode is disposed on the support; and
the package material of claim 1 disposed on the support and covering the light emitting diode.

11. The package of claim 10, wherein a projection area of the second molding portion projected on the support is larger than or equal to a projection area of the first molding portion projected on the support.

12. The package of claim 10, wherein the support has a recess, and the light emitting diode and the package material are located in the recess.

13. The package of claim 10, wherein a shape of an outer surface of the second molding portion is identical to a shape of an outer surface of the first molding portion.

14. The package of claim 10, wherein the package material further comprises a phosphor portion disposed on the second molding portion, the phosphor portion comprises a plurality of phosphor particles, and a projection area of the phosphor portion projected on the support is larger than or equal to a projection area of the second molding portion projected on the support.
